(19) United States
(12) Patent Application Publication
(10) Pub. No.: US 2009/0025584 A1
(43) Pub. Date: Jan. 29, 2009

(54) Method for Developing Printing Plates in an Offset Printing Press and Printing Press for Carrying out the Method

(75) Inventors: Thomas Bechberger, Ostringen (DE); Martin Dietze, Langen (DE); Axel Hauck, Karlsruhe (DE); Nikolaus Pfeiffer, Heidelberg (DE)

Correspondence Address: LERNER GREENBERG STEMER LLP, P O BOX 2480, HOLLYWOOD, FL, 33022-2480, US

(73) Assignee: HEIDELBERGER DRUCKMASCHINEN AG, Heidelberg (DE)

(21) Appl. No.: 12/178,931

(22) Filed: Jul. 24, 2008

(30) Foreign Application Priority Data
Jul. 24, 2007 (DE) 10 2007 034 880.2

(51) Int. Cl. B41L 25/00; G03F 7/00

(52) U.S. Cl. 101/147; 430/300

(57) ABSTRACT

A method for developing printing plates in a printing press having at least one printing unit includes loading an imaged, undeveloped printing plate with dampening solution before a start of printing for dampening in at least one printing unit of the printing press for an active duration corresponding at least to one and one half times a time duration or number of machine revolutions provided before a start of printing when an already developed printing plate is used in the same printing press. A printing press for carrying out the method is also provided.

### CROSS-REFERENCE TO RELATED APPLICATION

This application claims the priority, under 35 U.S.C. § 119, of German Patent Application DE 10 2007 034 880.2, filed Jul. 24, 2007; the prior application is herewith incorporated by reference in its entirety.

### BACKGROUND OF THE INVENTION

### Field of the Invention

The present invention relates to a method for developing printing plates in a printing press having at least one printing unit. The invention also relates to a printing press for carrying out the method.

In offset printing presses, printing plates which carry a printing image for a color separation are each situated in an individual printing unit. The printing plates are written in accordance with the color separations in order to apply the printing image to the printing plates. This writing of the printing plates takes place during the exposing process which can be performed, for example, through the use of a laser. Either the regions which print later or the regions which do not print later are modified by the exposure of the printing plate. The regions which are in each case not exposed and not written then have to be treated in a developing step, as a result of which finally the different surface quality of unwritten and written regions is set. In this case, the surface of the unwritten regions after the developing process usually has the property that those regions are ink-repelling, while the written regions of the printing plates are ink-accepting. Due to the supply of ink in the printing unit, the printing plates are then loaded in each case with the corresponding ink and transfer the printing image onto the blanket cylinder in a manner which is inked in this way. The blanket cylinder in turn interacts with an impression cylinder in the press nip. In this press nip, the ink is then transferred onto sheets or webs which are to be printed.

The printing plates are usually exposed outside the printing press in printing plate exposers. However, there are also printing presses which operate according to the principle of direct imaging (DI technology), in which the exposing device is situated in the printing unit in the immediate vicinity of the plate cylinder having the printing plate. In that case, the printing original is transmitted digitally in color separations to the printing plate exposer in the printing unit and is usually written there onto the printing plates of the printing plate cylinders through the use of a laser on site. Since the printing plates are not written until they are in the machine, as a consequence in those machines the printing plate also has to be developed in the machine. In the case of printing plates which are exposed outside the printing press, the printing plates can in turn be developed outside the printing press, or in the printing press. If the printing plates are developed in the printing press, that takes place by the application of the ink and dampening solution. Printing plates of that type which are to be developed in the machine are also called processless printing plates.

A printing press of that type for image setting in the machine is known from U.S. Patent Application Publication No. US 2007/0095232 A1. In that case, each printing unit has a laser image setting unit which is disposed in the region of the plate cylinder. The printing plates which are clamped on the plate cylinder can be written by way of the laser image setting device. Those regions of the printing plates which are written by way of the laser harden, while the unwritten regions are made blank and ink-repelling by a developing process in the machine through the use of ink and dampening solution. In order to improve the image setting through the use of laser, the printing units are covered with respect to incident light. That ensures that no light or only a little light having a wavelength which is shorter than 450 nanometers reaches the printing plates. Undesired reactions of the printing plate surface with incident daylight are therefore avoided.

However, during the developing of printing plates in the printing press through the use of the application of dampening solutions and ink, problems frequently result in reality, since either insufficient dampening solution or too much ink is applied. The application of dampening solution and ink usually takes place simply by the startup of the printing press for printing operation. As a result, however, the surface of the printing plate is often not developed in an optimum manner in the printing press, as a result of which the printing image later does not correspond to quality requirements. For that reason, many printing companies are very skeptical of the technology of developing in the printing press known as DoP (development on press). A solution to that problem cannot be gathered from U.S. Patent Application Publication No. US 2007/0095232 A1.

### SUMMARY OF THE INVENTION

It is accordingly an object of the invention to provide a method for developing printing plates in an offset printing press and a printing press for carrying out the method, which overcome the hereinafore-mentioned disadvantages of the heretofore-known methods and printing presses of this general type and which make it possible to develop a surface of the printing plate in the printing press in a manner which is reliable and reproducible for a printer.

With the foregoing and other objects in view there is provided, in accordance with the invention, a method for developing printing plates in a printing press having at least one printing unit. The method comprises loading an imaged, undeveloped printing plate with dampening solution before a start of printing for dampening in at least one printing unit of the printing press for an active duration corresponding at least to one and one half times a time duration or number of machine revolutions provided before a start of printing when using an already developed printing plate in the same printing press. Although particular printing speeds are mentioned below, in order to obtain the time or speed in revolutions per minute, the printing speed and the format of the press, that is the concrete length of the sheet and the printing speed, must be considered. Since this is format-dependent, a particular time cannot be given as an example.

With the objects of the invention in view, there is also provided a printing press, comprising at least one printing unit, a plate cylinder in the printing unit for receiving a printing plate, an inking unit in the printing unit, a dampening unit in the printing unit, and a control computer acting on a setting of the inking unit and the dampening unit and selectively carrying out a special program for dampening and developing exposed printing plates to be developed for an operating state before continuous printing. The special program for developing exposed printing plates is switched off automatically at a start of continuous printing.

The printing press according to the invention and the method according to the invention are suitable for use in all offset printing presses which make it possible to use printing plates that are to be developed in the printing press. This extends both to sheet-fed offset printing presses as well as to web-fed offset printing presses. While the normal print setup procedure which leads to the known problem is performed in the conventional DoP method for developing the exposed printing plates in the machine, the processes before preprinting operation are adapted and predefined specifically to the developing of the exposed printing plates in the printing press according to the present invention. If a newly imaged processless printing plate is inserted into the printing press or imaged in the machine in the case of a printing press having DI technology, the printing plate is thus provided first of all with dampening solution before the start of printing during an active duration which is at least one and one half times the time duration or number of machine revolutions more than the time duration for dampening when an already developed printing plate is used in the same printing press. A distinction is therefore made for the first time during startup of the printing press, in relation to the dampening, between the use of a newly imaged and not yet developed printing plate and an already developed printing plate. As a result of the time duration which is at least one and one half times as long or a corresponding number of machine revolutions, the dampening solution can act on the printing plate for a longer time than is possible during the conventional startup of the printing press. As a result, the upper plate layer which is to be removed during the developing process in the printing or nonprinting regions can swell in an improved manner, as a result of which reliable removal of the layer is ensured. In principle, in DoP technology, the surface of the plate layer is made to swell through the use of dampening solution, while the swollen plate layer is removed through the use of printing ink which is applied and the swollen plate layer is pulled off by adjacent rolls or cylinders. As a result of the thorough and considerably longer action of the dampening solution on the printing plate, however, the removal of the uppermost plate layer is improved enormously, as a result of which the print quality at the beginning of continuous printing is not substantially poorer than printing plates which have been developed conventionally outside the printing press.

In accordance with another mode of the invention, the active duration of the dampening solution for dampening the printing plate is divided into one or more separate dampening phases and into dampening before the start of continuous printing. The only important aspect is that the dampening overall takes a considerably longer time in the case of an undeveloped printing plate than in the case of an already developed printing plate.

In accordance with a further mode or first refinement of the invention, a small amount of ink is added to the dampening solution during developing of the printing plates in the printing press for an emulsion including ink and dampening solution. The use of an emulsion including ink and dampening solution proves advantageous, in particular, when the printing unit having an inking unit and a dampening unit has been washed previously after a print job change. As a result of the washing of the printing unit, there is then no longer any printing ink in the inking and dampening unit. It has proven favorable, however, for the developing process, if a small amount of ink is mixed with the dampening solution. If the inking and dampening unit has been washed, an input of ink has to be carried out before printing. Toward the end of the ink input, the dampening unit is also switched on and the printing plate is dampened by throwing on the dampening solution applicator roll. The processless plate comes into contact for the first time with dampening solution and the nonprinting points of the printing plate swell under the influence of the dampening solution and the dampening solution applicator roll. In order to obtain a favorable emulsion for improving the swelling process for the further developing process, the inking unit can be brought into connection with the dampening unit for a brief time, as a result of which a small amount of ink passes into the dampening unit, which is required for the formation of the emulsion including dampening solution and ink. Subsequent further dampening of the printing plate with the ink/dampening solution emulsion, which includes predominantly dampening solution, favors the further swelling of the plate. When the ink applicator rolls are thrown on, the swollen nonprinting image regions are removed from the printing plate relatively quickly by the ink and the plate runs free.

If the printing unit is not washed, a small amount of ink is automatically in the dampening unit, as a result of which the same conditions result by the addition of pure dampening solution. As a result of the introduction of an emulsion including ink and dampening solution into the washed printing unit, only the same state is therefore produced, as would also be produced in the case of an unwashed printing unit. However, it is very important in this case that the amount of ink remains very small, as a result of which the amount of dampening solution predominates considerably in every case.

In accordance with an added mode of the invention, in order to produce the emulsion including ink and dampening solution in the case of a washed printing unit, the inking unit can be thrown on briefly for a fraction of a revolution during the developing of the printing plate before the start of continuous printing, as a result of which the emulsion including a little ink and a large amount of dampening solution can be produced easily on the printing plate. The inking unit is thrown on briefly in this way during the swelling process and is not to be confused with the ink application which takes place after the swelling process in order to remove the layer which is to be pulled off from the printing plate. The process of swelling is to be carried out for such a long time that the printing plate is not clogged later by the application of ink during removal of the layer. This can be ensured only by sufficiently long dampening with a sufficient amount of dampening solution.

In accordance with an additional mode of the invention, ink is introduced for pulling off the developed plate layer before the start of continuous printing by throwing the inking unit onto the printing plate. In order to remove the swollen layer, the inking unit is thrown on temporally very closely to the start of continuous printing, so that an ink layer results on the sufficiently damp printing plate. As a result of the contact of the ink layer with the adjacent rolls of the inking and dampening unit or of the blanket cylinder, the uppermost swollen plate layer is then removed and the actual developing process is completed. The ink layer is required, in order to produce the corresponding pulling action on the swollen surface by the adjacent rolls and cylinders. As a result of the sufficiently long predampening process, the removal of the layer can be concluded after a few revolutions of the plate cylinder. In this case, as a rule, the printing plate is inked for three machine revolutions, before continuous printing begins. For continuous printing, the plate cylinder is then thrown onto the blanket cylinder, the paper run of sheet or web is switched on and the blanket cylinder is connected to the print medium.

In accordance with yet another mode of the invention, advantageously the dampening for developing the printing plate is performed at the maximum possible or an increased application of dampening solution of the dampening unit. In order to make the swelling process as short and effective as possible, regulators for the application of dampening solution are to be set to the maximum possible amount of dampening solution during developing of the printing plate. This ensures that sufficient dampening solution is applied in as short a time as possible to the printing plate which is to be developed.

In accordance with yet a further mode of the invention, a further advantage results by virtue of the fact that the dampening for developing the printing plate is performed with a quantity of dampening solution which is variable over time or as a function of the machine revolutions. The amount of dampening solution can therefore be adapted by the control computer of the printing press in an optimum manner to the developing process through the use of characteristic curves and as a function of the machine speed.

In accordance with yet an added mode of the invention, a further advantage results by virtue of the fact that the application of dampening solution takes place at relatively low printing speeds, in particular between 2,000 and 9,500 sheets per hour in sheet-fed printing presses. An operating speed of the printing press which is considerably slower than continuous printing speeds of over 18,000 sheets per hour has improved the application of dampening solution further in tests. The same reduced speed has also proven favorable during the short application of ink for pulling the layer off of the printing plate. The pulling off of the layer by the ink applicator rolls which are thrown onto the plate cylinder preferably takes place without paper running being switched on, as a result of which no unnecessary waste paper is produced.

In accordance with yet an additional mode of the invention, after developing of the printing plates, all of the printing units of the printing press are switched over to continuous printing at the same printing speed. Since, in this case, all of the printing units are switched over to continuous printing at the same printing speed, the same states also result on all of the printing units during removal of the layer after the application of ink. In the same way that the application of dampening solution or the application of the emulsion including dampening solution and ink also takes place if possible at low printing speeds between 2,000 and 9,500 sheets per hour in sheet-fed printing presses, the switchover to continuous printing operation should also take place at a relatively low printing speed between 2,000 and 9,500 sheets per hour in sheet-fed printing presses. The removal of the layer during switchover to continuous printing operation is more successful at this relatively low printing speed.

In accordance with again another mode or particularly advantageous refinement of the invention, the printing press has a control computer and the control computer acts on the settings of the inking unit and the dampening unit in the printing press, and the control computer has the selection possibility of a special program for dampening and developing exposed printing plates for the operating state before continuous printing. This ensures that the developing of the exposed printing plates in the machine does not take place with the amount of dampening solution and ink which is required during normal startup, but rather that sufficient time is given for the required swelling process for correct removal of the layer in the unexposed or exposed regions of the printing plate which is to be developed. When the printer has inserted a new exposed printing plate into the printing press, he or she can select the program “DoP” which automatically makes the corresponding steps possible for optimum swelling and subsequent removal of the layer. This has the great advantage that this program is reproducible and the printer does not himself or herself have to set a halfway suitable application of dampening solution and ink for developing the printing plate from the innumerable number of settings for the inking and dampening unit. This avoids a developing process of the printing plate which is set incorrectly and is affected by faults with immanent quality problems, and makes the use of the DoP printing plates interesting for the first time for most printers.

In accordance with again a further mode of the invention, a sensor is provided in the printing press for distinguishing between a developed and an undeveloped printing plate in at least one printing unit. A sensor of this type can sense the surface of the inserted printing plate and determine whether or not there are regions on the printing plate which have already been removed. In this case, the sensor would detect an already developed printing plate, as a result of which the special program for developing the printing plate does not need to be used. If, however, the sensor cannot detect a removed layer on the printing plate, it is to be assumed that it is a new exposed but not yet developed printing plate, for the developing of which the special program for dampening and developing has to be used. The special program for developing the printing plate automatically in the printing press can be carried out as a function of the detection results of the sensor. As an alternative, there can also be provision for the printer to be given the indication first of all on a display screen optically, or acoustically in another embodiment, that a new printing plate which has not yet been developed has been inserted and the selection of the special program for developing is offered to the printer. The printer can then start the special DoP program by inputting an acknowledgement. It goes without saying that a purely manual selection of printing units by the operating staff is also conceivable, with the special DoP program then being carried out in the manually selected printing units. However, this process is not protected against false inputs by the printer.

In accordance with again an added mode of the invention, the special program for developing the exposed printing plate is switched off automatically with the start of continuous printing. Since the special program is appropriate only in the case of new printing plates which have not yet been developed, the automatic switching off after the start of continuous printing can ensure that the special program for developing is not started accidentally and unnecessarily in the case of a new print start with the same printing plate or another printing plate which has already been developed. Even if the printer forgets that he or she does not need the special program in the case of an already developed printing plate, this embodiment ensures automatically that the special program is not accidentally used in the case of a developed printing plate.

In accordance with again an additional mode of the invention, the printing press has a plurality of printing units for receiving printing plates which have been developed outside and inside the printing press, and the special DoP program for developing the printing plate in the printing press is selected by the control computer through the use of the sensors in the printing units, only in each case for printing units having inserted printing plates which are to be developed. Printing plates which are to be developed both outside and inside the printing press can be used in a printing press of this type with high operational security. Since the sensor can distinguish between developed and undeveloped printing plates, the printer does not have to worry about the correct treatment of the printing plates. The special DoP program for developing printing plates is started as a function of the plate which is detected by the sensors only in the respectively relevant printing unit, automatically or after an indication to the printer in the case of the printing plates which have not yet been developed. However, the special program is not required and is also not used in the printing units having printing plates which have been developed outside the printing press. Operating errors by the printer are therefore reduced to a minimum and the reliable operation of different printing plates in a printing press is also ensured.

In accordance with a concomitant mode of the invention, the sensor or an additional camera can also be used for monitoring a coat removal process during developing of the printing plate. If insufficient coat removal is determined, the control computer can add more dampening solution in the future or slow down the pulling off of the layer, until the printing plate is clean, and thus intervene in the developing process in an optimizing manner.

Other features which are considered as characteristic for the invention are set forth in the appended claims.

Although the invention is illustrated and described herein as embodied in a method for developing printing plates in an offset printing press and a printing press for carrying out the method, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE SEVERAL VIEWS OF THE DRAWING

FIG. 1 is a diagrammatic, longitudinal-sectional view of a multiple color sheet-fed offset printing press, a perspective view of a control computer and a side-elevational view of a connected printing plate exposer;

FIG. 2 is a flow chart showing a selection possibility of a special DoP program for developing printing plates in the printing press;

FIG. 3 is a flow chart showing operations during developing of a printing plate in the printing press;

FIG. 4 is a diagram of a first variant of a special DoP program for developing printing plates in the printing press with extended predampening;

FIG. 5 is a diagram of a second variant of a special DoP program for developing printing plates in the printing press with separate dampening and extended predampening; and

FIG. 6 is a diagram of a third variant of a special DoP program for developing printing plates in the printing press with separate plate dampening and coat removal.

### DETAILED DESCRIPTION OF THE INVENTION

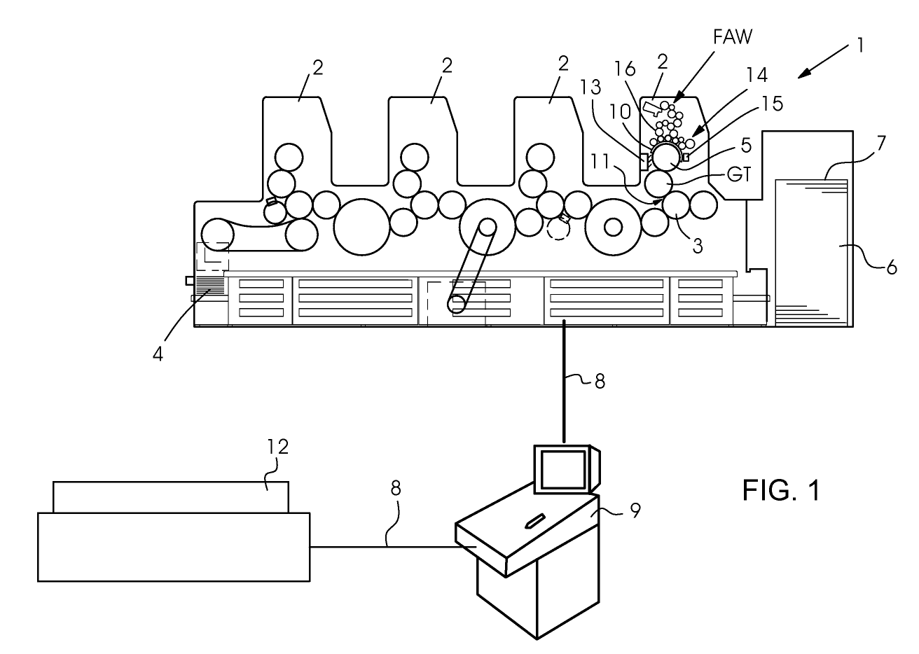

Referring now to the figures of the drawings in detail and first, particularly, to FIG. 1 thereof, there is seen a sheet-fed offset printing press 1 having four printing units 2. Each of the four printing units 2 has an inking unit FAW and a dampening unit 14. Plate cylinders 5 in the printing units 2 are loaded with printing ink during printing operation from the inking unit FAW through inking unit rolls 16. Moreover, each of the printing units has a dampening unit 14 in order for it to be possible to influence the consistency of the printing ink in the inking unit FAW. The dampening unit 14 dispenses dampening solution to the inking unit FAW, in order for it thus to be possible to change the consistency of the ink. The inking unit FAW and the dampening unit 14 can be thrown separately onto the plate cylinder 5, and the dampening unit 14 and the inking unit FAW can also be thrown off one another. The plate cylinder 5 carries a printing plate 10 which contains the color separation for the respective printing unit 2. The color separations on the printing plates 10 of the printing units 2 are produced in a prepress stage by breaking the printing original down into individual printing colors. There is a printing plate exposer 12 in the prepress stage for exposing the printing plate 10 with the respective color separation. Printing regions of the printing plate 10 are written through the use of a laser in this printing plate exposer 12, as a result of which the properties of the surface in the printing regions change. After writing in the printing plate exposer 12, the printing plates 10 can be clamped onto the plate cylinders 5 in the printing press. In the case of processless printing plates according to the DoP principle, developing, that is to say removal of the upper layer of the printing plate 10 in the nonprinting regions, takes place in the printing press 1.

In order to remove the layer in the nonprinting regions on the printing plate 10, the printing plate 10 is dampened with dampening solution from the dampening unit 14. This takes place for at least one and one half times as long as the time duration or as high a number of revolutions in the printing press 1 as is the case in printing plates 10 which have already been developed fully. As a result of this considerably extended dampening which can certainly also be carried out for four to five times as long as in the case of the developed plates 10, the surface of the printing plate 10 swells in the unexposed regions. The surface which is swollen in this way can be removed from the printing plate 10 by an application of ink from the inking unit FAW. As a result of the adhesion of the ink on the uppermost layer of the processless plate 10 and in turn the adhesion of the ink on a blanket cylinder GT, the swollen up layer of the printing plate 10 is torn off and thus removed after a few revolutions of the printing press 1. As a rule, three machine revolutions are sufficient before continuous printing operation begins. In continuous printing operation, the printing plate 10 on the plate cylinder 5 is supplied with sufficient printing ink from the inking unit FAW. This printing ink is transferred onto the surface of the blanket cylinder GT when the blanket cylinder GT is thrown on. The blanket cylinder GT is in turn thrown onto an impression cylinder 3 during printing operation, as a result of which the ink from the blanket cylinder GT can be transferred onto printing material 7 in a press nip 11 between the impression cylinder 3 and the blanket cylinder GT.

In the sheet-fed printing press 1, the printing materials 7 are removed from a feeder 6 and are transported over cylinders through the individual printing units 2. The sheet-fed printing press 1 has a delivery 4, located after the last printing unit 2, in which the finished printed sheets 7 are deposited. A drive motor for the sheet-fed printing press 1 and actuating motors in the dampening unit 14 and the inking unit FAW can be actuated through an operating desk 9 having a control computer. The control computer in the operating desk 9 is configured in such a way that it can perform the necessary regulating operations largely automatically, in particular on the dampening unit 14 and the inking unit FAW. The operating staff can perform settings on the printing press 1 and read off the operating state through a display screen. To this end, the operating desk 9 is connected to the electronic control devices of the printing press 1 through a communications link 8. Furthermore, the operating desk 9 is connected to the printing plate exposer 12 in the prepress stage through a communications link 8. In this way, the printing press 1 can also exchange data with the prepress stage through the use of the operating desk 9. Moreover, the control computer in the operating desk 9 contains a special control program for removing the unexposed layer on processless printing plates 10. The printer may initiate this special DoP program manually on the operating desk 9 if he or she has inserted an exposed but not yet developed printing plate 10 into one of the printing units 2. Alternatively, there is a sensor 15 in each of the printing units 2, which senses the inserted printing plates 10 optically and detects an exposed but not yet developed printing plate 10 due to changed surface properties. If the sensor 15 reports a printing plate 10 of this type to the operating desk 9, the operator receives an indication on a display screen on the operating desk 9 that he or she should start the special DoP program for removing the layer in the unexposed regions for this printing unit 2. The computer in the operating desk 9 can also be configured in such a way that the special DoP program for removing the layer in the unexposed regions is carried out automatically when a not yet developed printing plate 10 is detected by the sensor 15 in the relevant printing unit 2. Furthermore, there is a camera 13 in the printing unit 2 in FIG. 1. The camera 13 is connected to the operating desk 9 having the control computer. This camera 13 monitors the removal of the developed layer from the printing plate 10, as a result of which the control computer in the operating desk 9 can optimize the various parameters using the data of the camera 13 during dampening, developing and pulling off of the layer from the printing plate 10 through the use of printing ink.

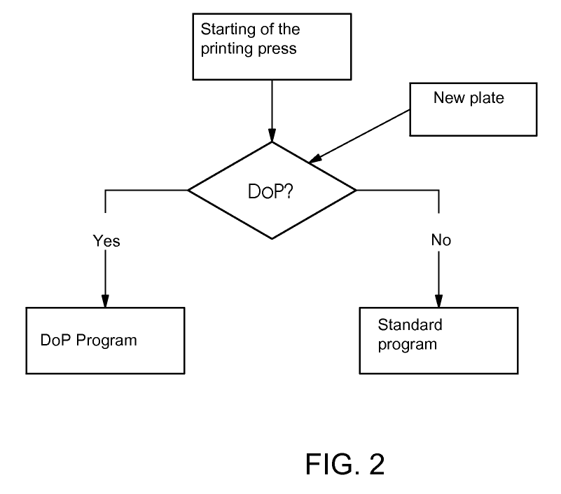

FIG. 2 indicates the operation during the selection of the special DoP program for removing the layer and for developing the plate 10. Either the printer informs the control computer in the operating desk 9 manually that he or she has inserted a new undeveloped printing plate 10 into one of the printing units 2, or the insertion of a plate of this type is detected automatically by the sensor 15 in the printing unit 2. If a printing plate 10 of this type is detected, the special DoP program for removing the layer is used. A plurality of variants of this program will be described in greater detail with the aid of the other figures. If, however, there are only printing plates 10 which have already been developed in the printing units 2 of the printing press 1, the normal standard program starts, by way of which the sheet-fed printing-press 1 is started.

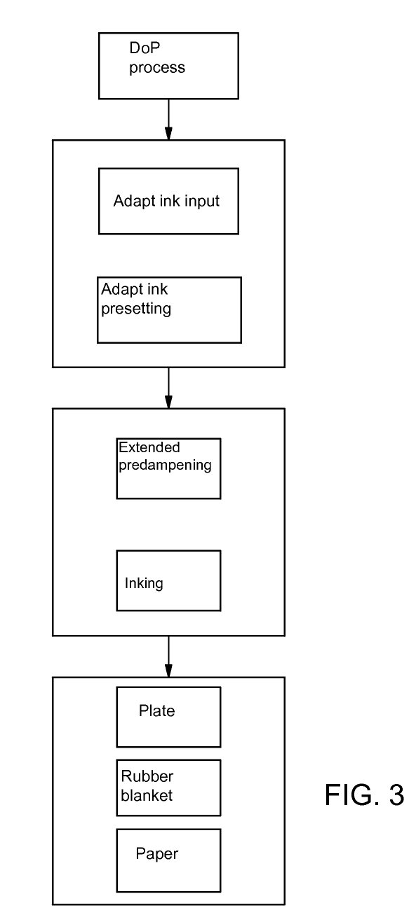

According to FIG. 3, the special DoP program for removing the layer includes a plurality of processes. In contrast to normal startup of the printing press 1 with developed printing plates 10, an adapted input of ink and an adapted ink presetting are performed in the case of undeveloped processless printing plates 10. As its core, the DoP program includes a special predampening process which lasts a relatively long time and by way of which the swelling of the surface of the printing plate 10 is ensured sufficiently. In order to remove the swollen layer in the unexposed regions on the printing plate 10, the surface of the printing plate 10 is inked briefly, as a result of which the inked swollen regions come into contact with the ink applicator rolls 16 of the inking unit FAW and the layer of the printing plate 10 can be pulled off and the printing plate is thus developed. After developing of the plate 10 on the plate cylinder 5 in the printing units 2, the plate cylinder 5 is brought into contact with the blanket cylinder GT and the blanket cylinder GT is thrown onto the impression cylinder 3. Before this, paper running is switched on, as a result of which the first printing sheets 7 reach the press nip 11 in the printing units 2 before the impression cylinder 3 and the blanket cylinder GT are thrown onto one another. Continuous printing operation is therefore achieved and the production of the printing materials 7 can begin.

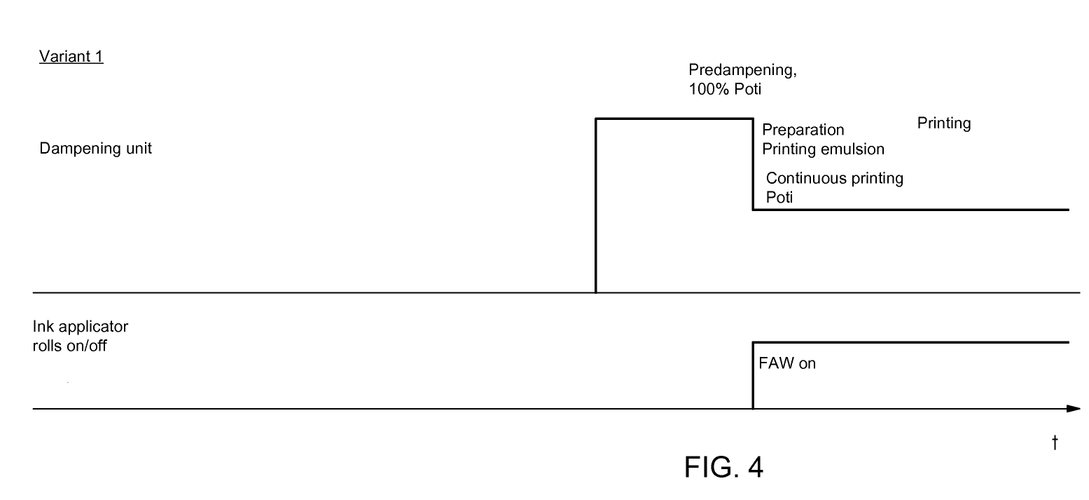

A first variant of a program for removing the unexposed upper layer of the printing plate 10 can be gathered from FIG. 4. As is also the case in the following variants, a time axis t extends from the left to the right in the developing phase of the printing plate 10 and the start of continuous printing. The dampening unit 14 and the ink rolls 16 of the inking unit FAW in a printing unit 2 which are switched on and off from time to time during developing of the printing plate 10 are listed from top to bottom. Settings of the amount of dampening solution in the dampening unit 14 are performed through the use of a potentiometer Poti on the operating desk 9 of the printing press 1. In the first variant 1 in FIG. 4, first of all dampening is carried out with the maximum application of dampening solution for a relatively long time duration or a relatively high number of machine revolutions, which is also called predampening, in order to make the nonprinting layer of the plate 10 swell. To this end, the setting of the potentiometer Poti on the dampening unit 14 is 100%. Directly thereafter, the setting of the potentiometer Poti is reduced and the swollen plate layer is pulled off when the ink applicator rolls 16 are thrown on. The printing emulsion including dampening solution and ink is then set for continuous printing operation. Continuous printing then begins after a few revolutions of the plate 10 on the plate cylinder 5.

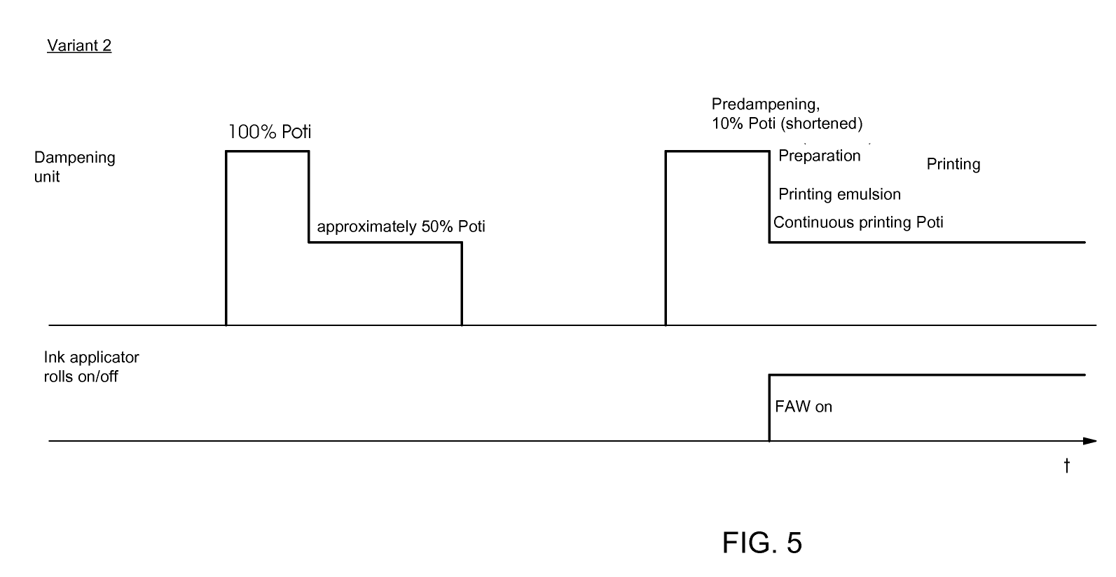

In the second variant in FIG. 5, first of all predampening is carried out with the maximum application of dampening solution. To this end, the setting of the potentiometer on the dampening unit 14 is 100%. After a relatively short time, the application of dampening solution is reduced to approximately 50% for the continuous printing setting of the potentiometer Poti. Subsequently, the normal program for preparing continuous printing operation starts, in which first of all the developed printing plate 10 is predampened with an extended predampening duration and maximum dampening solution and then the swollen plate layer is pulled off with a reduced setting on the potentiometer Poti and by throwing the ink applicator roll 16 onto the printing plate 10. Subsequently, the printing emulsion including dampening solution and ink is set. Continuous printing begins after a few revolutions of the plate 10 on the plate cylinder 5.

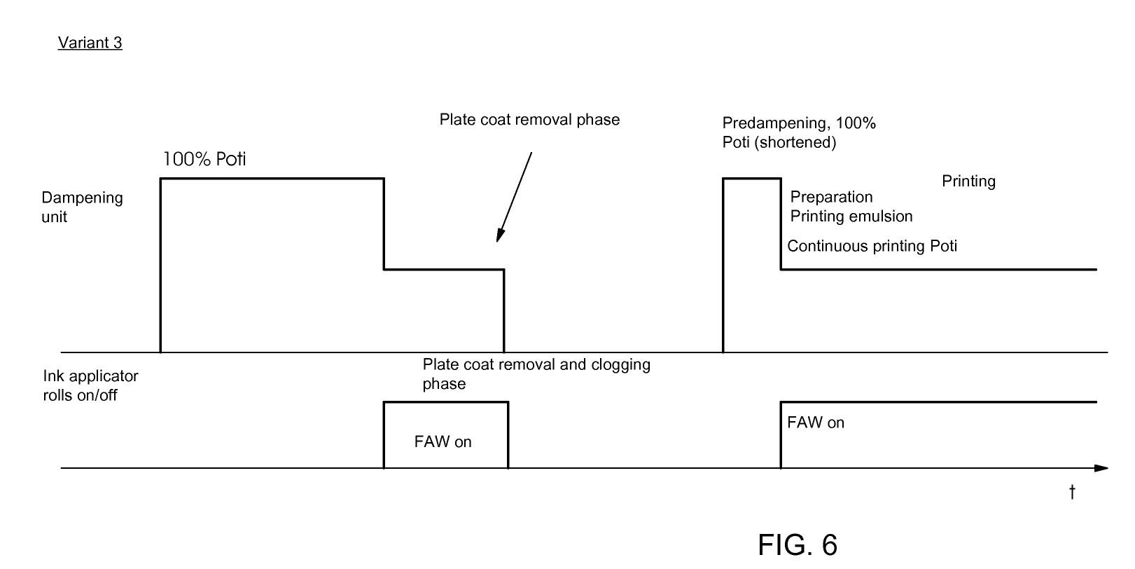

In the third variant 3 according to FIG. 6, first of all predampening is carried out with the maximum application of dampening solution for a relatively long time duration or a relatively high number of machine revolutions, in order to make the nonprinting layer of the plate 10 swell. To this end, the setting of the potentiometer on the dampening unit 14 is 100%. Directly thereafter, the setting of the potentiometer Poti is reduced and the swollen plate layer is pulled off when the ink applicator rolls 16 are thrown on. In contrast to the first variant in FIG. 4, continuous printing does not then begin, but rather the process is ended after a few revolutions of the plate 10 on the plate cylinder 5. The plate 10 has then been developed fully and can remain in the machine 1 until the printer desires to activate continuous printing. With the activation of continuous printing, the normal starting program including predampening and subsequent throwing on of the ink applicator roll 16 for setting the printing emulsion including ink and dampening solution is executed, before actual printing begins.

A common feature of the variants 1 to 3 is that the total of plate dampening and predampening takes at least one and one half times as long as in print preparation in the case of printing plates 10 which have already been developed. This ensures that the surface of the printing plate which has not yet been developed can swell sufficiently, as a result of which the nonimaged regions of the printing plate 10 can be removed quickly and cleanly within a few revolutions of the printing press 1 when the ink applicator rolls 16 are thrown on.

1. A method for developing printing plates in a printing press having at least one printing unit, the method comprising the following steps:
loading an imaged, undeveloped printing plate with dampening solution before a start of printing for dampening in at least one printing unit of the printing press for an active duration corresponding at least to one and one half times a time duration or number of machine revolutions provided before a start of printing when using an already developed printing plate in the same printing press.

2. The method according to claim 1, which further comprises exposing the printing plate outside the printing press.

3. The method according to claim 1, which further comprises dividing the active duration of the dampening solution for dampening the printing plate into one or more separate dampening phases and into dampening before the start of continuous printing.

4. The method according to claim 1, which further comprises adding a small amount of ink to the dampening solution during developing of the printing plate in the printing press for an emulsion including ink and dampening solution.

5. The method according to claim 1, which further comprises, before commencing continuous printing, applying ink to the printing plate for pulling off a developed plate layer, by throwing on an inking unit.

6. The method according to claim 1, which further comprises, before or during throwing on an inking unit, supplying the printing plate with a maximum possible or an increased application of dampening solution with a dampening unit.

7. The method according to claim 1, which further comprises, after washing an inking unit and a dampening unit and after an ink input and first dampening of the printing plate to be developed, briefly connecting the inking unit in contact with the dampening unit.

8. The method according to claim 1, which further comprises performing the dampening of the plate with a dampening unit thrown onto the printing plate and with an inking unit thrown off the printing plate.

9. The method according to claim 1, which further comprises separating a dampening unit and an inking unit from one another during dampening of the plate.

10. The method according to claim 9, which further comprises carrying out the step of separating the dampening unit and the inking unit from one another for more than half the time duration of the dampening, during dampening of the plate.

11. The method according to claim 1, which further comprises carrying out the dampening for developing the printing plate at a maximum possible or an increased application of dampening solution of a dampening unit.

12. The method according to claim 1, which further comprises carrying out the dampening for developing the printing plate with a quantity of dampening solution being variable over time or as a function of the machine revolutions.

13. The method according to claim 1, which further comprises carrying out the dampening of the plate during a separate dampening phase.

14. The method according to claim 1, which further comprises carrying out the dampening for developing the printing plate in a separate dampening phase, by performing a high or maximum application of dampening solution of a dampening unit at a beginning of the dampening phase and subsequently performing a lower application of dampening solution in a further course of the dampening phase.

15. The method according to claim 4, which further comprises carrying out the application of dampening solution or an application of the ink/dampening solution emulsion at relatively slow printing speeds.

16. The method according to claim 4, which further comprises carrying out the application of dampening solution or an application of the ink/dampening solution emulsion at printing speeds between 2,000 and 9,500 sheets per hour in sheet-fed printing presses.

17. The method according to claim 1, which further comprises throwing on ink applicator rolls of an inking unit at relatively slow printing speeds, in order to pull off a developed plate layer from the printing plate.

18. The method according to claim 1, which further comprises throwing on ink applicator rolls of an inking unit at printing speeds between 2000 and 9500 sheets per hour in sheet-fed printing presses, in order to pull off a developed plate layer from the printing plate.

19. The method according to claim 1, which further comprises switching over all of the printing units of the printing press to continuous printing at the same printing speed, after developing the printing plates.

20. The method according to claim 19, which further comprises switching over all of the printing units to continuous printing at a relatively low printing speed, in sheet-fed printing presses.

21. The method according to claim 19, which further comprises switching over all of the printing units to continuous printing at a printing speed between 2,000 and 9,500 sheets per hour, in sheet-fed printing presses.

22. The method according to claim 1, which further comprises carrying out the dampening of the printing plate and throwing on of ink applicator rolls in order to pull off the developed plate layer from the printing plate, in a separate phase, without sheets being printed.

23. A printing press, comprising:
at least one printing unit;
a plate cylinder in said printing unit for receiving a printing plate;
an inking unit in said printing unit;
a dampening unit in said printing unit; and
a control computer acting on a setting of said inking unit and said dampening unit and selectively carrying out a special program for dampening and developing exposed printing plates to be developed for an operating state before continuous printing, said special program for developing exposed printing plates being switched off automatically at a start of continuous printing.
